(19) United States
(12) Patent Application Publication
(10) Pub. No.: US 2009/0015997 A1
(43) Pub. Date: Jan. 15, 2009

(54) Modular and Configurable Display Device

(75) Inventors: Leandro G. Barajas, Troy, MI (US); Christopher M. Santella, Rochester Hills, MI (US); Rodney Schultz, Davisburg, MI (US)

Correspondence Address: GENERAL MOTORS CORPORATION;LEGAL STAFF, MAIL CODE 482-C23-B21, P O BOX 300, DETROIT, MI, 48265-3000, US

(73) Assignee: GM GLOBAL TECHNOLOGY OPERATIONS, INC., DETROIT, MI (US)

(21) Appl. No.: 11/776,700

(22) Filed: Jul. 12, 2007

(51) Int. Cl. H05K 5/02

(52) U.S. Cl. 361/681

(57) ABSTRACT

A modular display device includes a housing module having a plurality of open face compartments and a back wall having access openings therein registering with each of the open face compartments. A circuit board is mounted on the back wall of the housing module and carries a plurality of light-emitting diodes mounted thereon and being energizable by the circuit board to shine through the access openings and light up the compartment. A lens is provided for each of the compartments and attached to the housing module to close the open face compartment. Each lens has an alphanumeric or other message thereon which will be backlit by the light-emitting diodes so that information is displayed. A plurality of these housing modules are mounted together side by side in order to form a display board of scalable and customizable size depending upon the number of information messages to be displayed and signaled.

### FIELD OF THE INVENTION

The present invention relates to a modular display device, and more particularly, relates to a configurable display board assembled from a plurality of display modules.

### BACKGROUND OF THE INVENTION

It is well known in modern manufacturing facilities to employ a signboard-like display device to notify management and workers of a quality or process problem. The display device incorporates signal lights, audio alarms, and text or other displays of relevant information. This signal can be triggered either by the manual activation by a worker, perhaps signaling a part shortage or a tool malfunction, or the signal can be automatically activated by connecting the controls of the signal device with the controls of a conveyor or other machinery. Such display devices are commonly referred to as an Andon system, the term Andon originating in the fact that Japanese manufacturing companies borrowed the word Andon from the Japanese word for a paper lantern.

Heretofore, such display devices have been expensive and had to be custom engineered and manufactured depending upon the size of the signal device desired, which in turn is dependent on the number of different messages that need to be conveyed in a particular display device at a particular work station in a particular factory.

Accordingly, it would be desirable to have a display device that could be constructed of standard modules that could be assembled in an array of any size to make a display board, and that could be readily disassembled and reconfigured as changes are made in a manufacturing process or other application for which the display board is used to display information.

### SUMMARY OF THE INVENTION

A modular display device is comprised of a housing module having a plurality of open face compartments. The housing module includes a back wall having an access opening therein registering with each of the open face compartments. A circuit board is mounted on the back wall of the housing module and carries a plurality of light-emitting diodes mounted thereon and being energizable by the circuit board to shine through the access openings in the back wall of the housing module. A lens is provided for each of the compartments and is attached to the housing module to close the open face compartment. Each lens has an alphanumeric or other message thereon which will be backlit by the light-emitting diodes upon selective energization of the light-emitting diodes so that information is displayed. A plurality of these housing modules are mounted together side by side in order to form a display board of scalable and customizable size depending upon the number of information messages that are desired to be displayed and signaled.

Further areas of applicability of the present invention will become apparent from the detailed description provided hereinafter. It should be understood that the detailed description and specific examples, while indicating exemplary embodiments of the invention, are intended for purposes of illustration only and are not intended to limit the scope of the invention.

### BRIEF DESCRIPTION OF THE DRAWINGS

The present invention will become more fully understood from the detailed description and the accompanying drawings, wherein;

FIG. 1 is an exploded view of a display module to show its components, including a module housing, a circuit board, and a back cover;

FIG. 2 is a top view of a display module;

FIG. 3 is a front elevation view of the display module of FIGS. 1 and 2;

FIG. 4 is a perspective view showing a plurality of the display modules assembled together to form a large scale display board of the desired size and configuration; and

FIGS. 5 and 6 show rear views of large scale display boards and schematics of the wiring architecture for connecting a plurality of the display boards.

### DESCRIPTION OF THE INVENTION

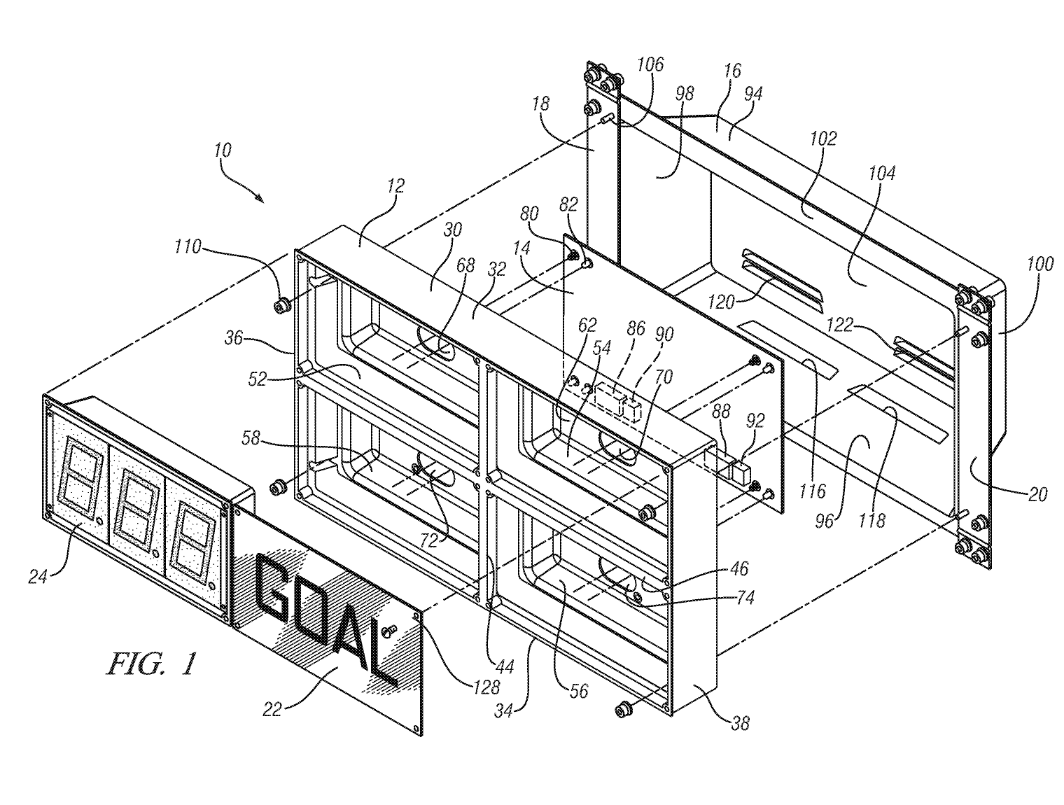

Referring to FIG. 1, a display module 10 is shown in exploded view and includes a housing module 12, a circuit board 14, a back cover 16, left hand mounting bracket 18, right hand mounting bracket 20, lens 22, and display 24.

The housing module 12 is preferably a molded plastic box 30 having a top wall 32, bottom wall 34, left side wall 36, and right side wall 38. However, it is appreciated that the housing module 12 may be formed from other materials, e.g., aluminum, graphite or wood, and may be provided in various configurations. The box 30 is divided into open face compartments by a center vertical wall 44 and a center horizontal wall 46. Thus, as seen in FIG. 1, the box 30 provides separate compartments 52, 54, 56, and 58, each of which has an open face for receiving and mounting either a lens, such as the lens 22, or a display, such as the display 24, as will be discussed further hereinafter. The box 30 has a back wall 62 that closes off the back of each of the compartments 52, 54, 56, and 58. The back wall 62 has access openings 68, 70, 72, and 74 therein which are generally centered in each of the compartments 52, 54, 56, and 58.

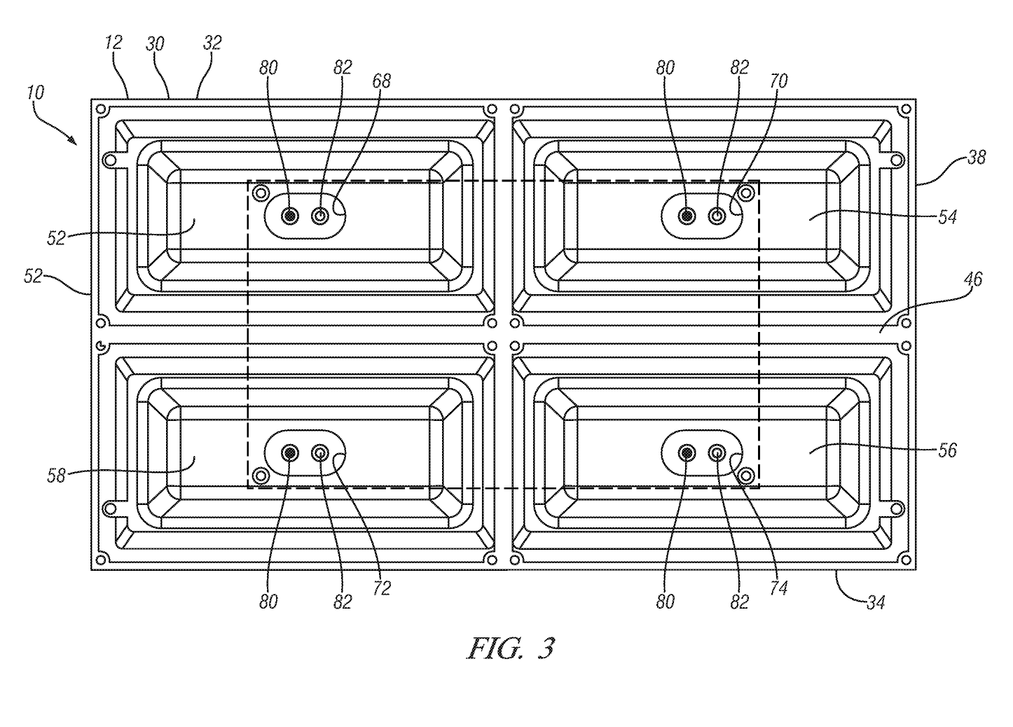

The circuit board 14 carries electronic circuitry and also mounts light-emitting diodes that register with the access openings 68, 70, 72 and 74. In particular, as best seen in FIG. 3, the circuit board 14 has a red diode 80 and a yellow diode 82 that are mounted side-by-side within the access opening 68 of compartment 52 when the circuit board 14 is attached onto the back wall 62 of the box 30. Other light-emitting diodes 80 and 82 are mounted at each of the other corners of the circuit board 14 and respectively register with the access openings 70, 72 and 74 of the open face compartments 54, 56, and 58. Dip switches 86 and 88 are mounted on the circuit board 14 at the lower edge thereof. Input/output electrical connectors 90 and 92 are mounted on the circuit board 12 adjacent to the dip switches 86 and 88.

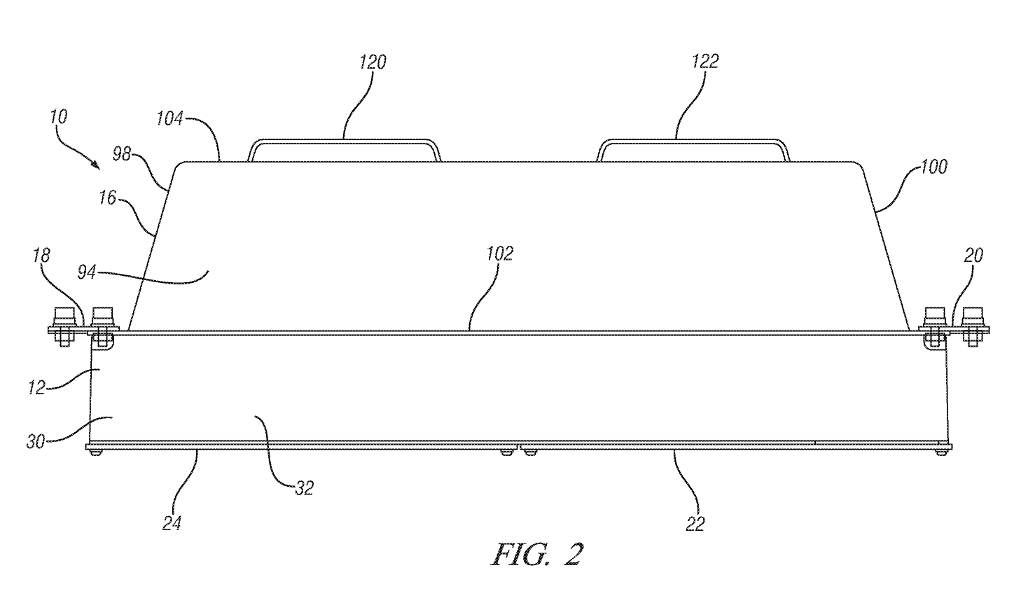

Referring to FIGS. 1 and 2, the back cover 16 of the display module 10 is a molded plastic or stamped metal pan that fits over the circuit board 14 to protect and cover the circuit board 14. In particular, the back cover 16 includes a top wall 94, a bottom wall 96, a left hand wall 98, and a right hand wall 100, as well as a peripheral flange 102 and a back wall 104. The left hand bracket 18 is attached to the peripheral flange 102 of the back cover 16 by a screw 106, which also reaches through the back wall 62 of the box 30 and receives a nut 110. A similar screw and nut attachment is made at the lower end of the bracket 18 and similar attachments are made at the right-hand bracket 20 so that the back cover 16 is attached onto the back side of the box 30. The back cover 16 has access slots 116 and 118 in the bottom wall 96 so that electrical connectors, not shown, can be inserted upwardly through the slots 116 and 118 to connect with the input/output electrical connectors 90 and 92. In addition, the slots 116 and 118 are large enough to allow a technician to make manual adjustments of the settings of the dip switches 86 and 88. Also, access slots 116 and 118 can act as a water drain in the event that condensation or other liquid somehow enters the display module 10. It is also seen in the drawings, FIGS. 1 and 2 that air vent slots 120 and 122 are provided in the back wall 104 of the back cover 16 to allow air flow for venting away any heat buildup from the circuit board 14.

As seen in FIG. 1, the lens 22 will be attached within the open face compartment 54 by screws or plastic retainers, one of which is shown at 128. The lens 22 is preferably transparent or translucent plastic sheeting, which has an alphanumeric message stenciled thereon. Accordingly, when the light-emitting diodes are illuminated by the circuit board 14, the illumination fills the open face compartment 54 and backlights the lens 22 to thereby draw attention to the message stenciled on the lens 22.

FIG. 1 also shows that one or more of the open face compartments, in this case the open face compartment 52 can be filled with a display 24 instead of a lens 22. The display 24 is commercially available and is comprised of a plurality of 7-segment light-emitting diodes, often referred to as a seven segment display, which can display either numbers or alphabet characters. Thus the display 24 can act as a counter or as a message display. The display 24 is connected to the circuit board 14 by standard connectors and wiring, not shown in the drawing.

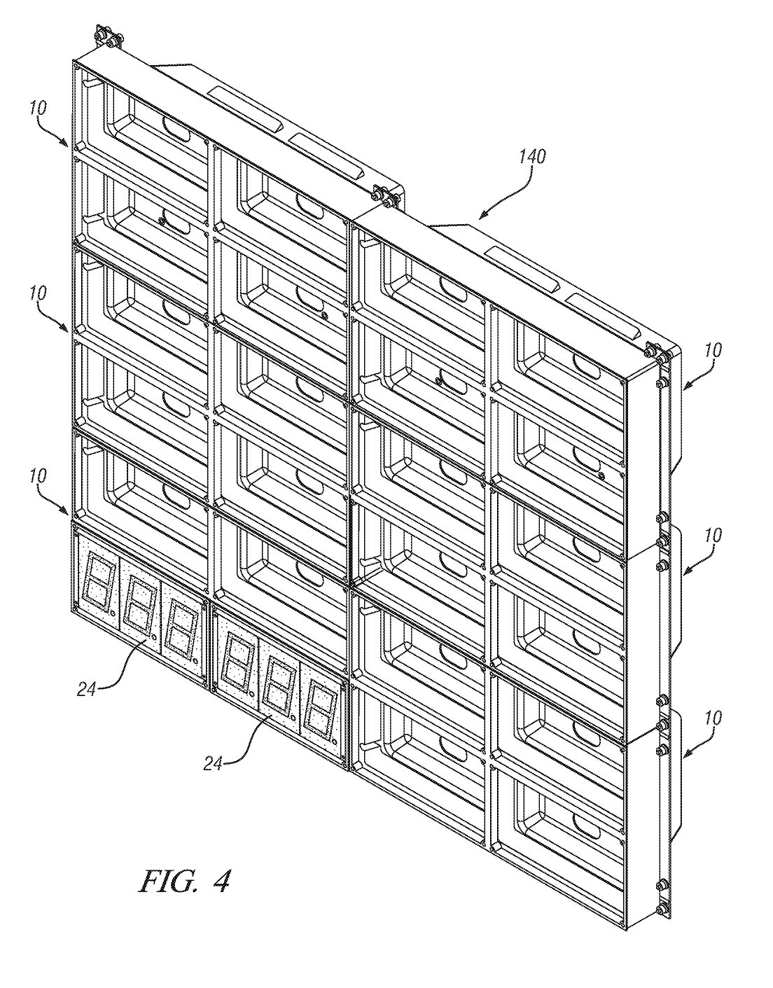

Referring now to FIG. 4, a large scale display board 140 is shown that has been made by stacking together and attaching together six of the display modules 10 of FIG. 1. It will be seen and appreciated that the attachment together of these display modules 10 has been facilitated by the left-hand mounting brackets 18 and right-hand mounting brackets 20 provided on each of the housing modules 12. Additional display modules 10 can be added as desired to make the display board 140 of any size that is needed to accommodate the display of as many information messages as desired.

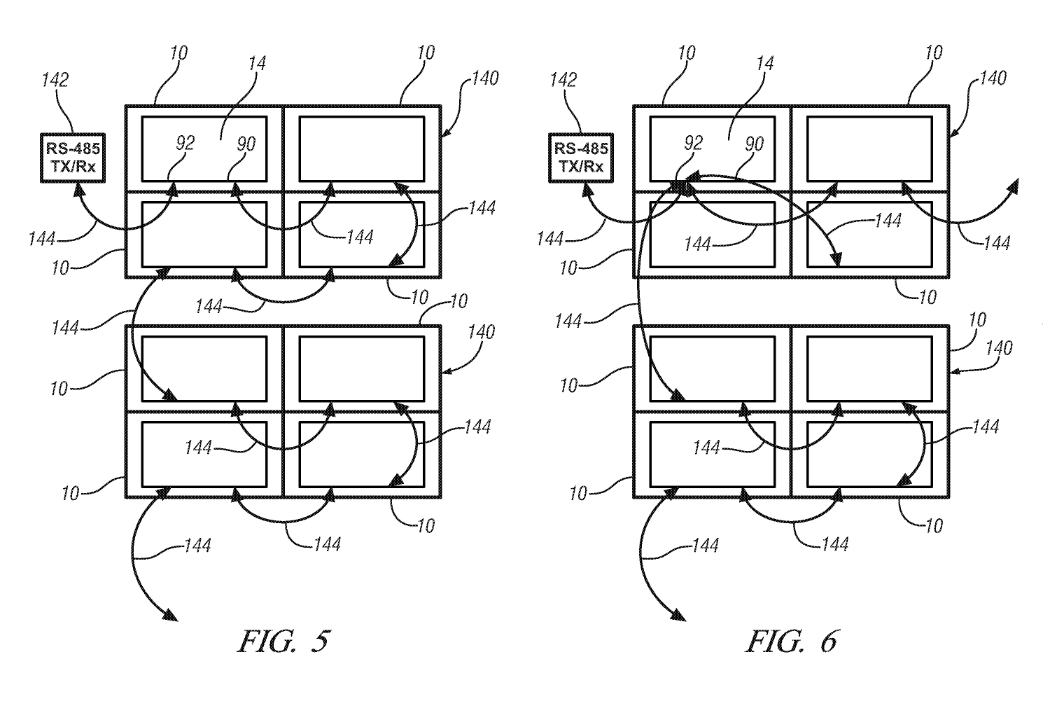

Referring to FIG. 5, there is shown an electrical architecture for connecting the display boards 140. In FIG. 5, two of the display boards 140 are shown, and each is assembled of four of the display modules 10. The display modules 10 are connected together, and to a driver 142, by a number of four-wire cables 144 that connect to the input/output electrical connectors 90 and 92. Each of the four-wire cables including two wires for power and two wires for Ethernet signal communication via the RS-485 electrical standard specification, in which each of the circuit boards serves as a node or station which is recognized by the driver 142. The dip switch 88 can set up the group address that will correspond to the board group, and the dip switch 86 can set up the unit address, which will correspond to an individual display within the display board 140. If an eight-position dip switch is used, 256 possible combinations are available

In FIG. 5, the cables 144 connect the display modules 10 by a series point-to-point electrical connection. The display board 140 can be located up to 4,000 feet apart within the plant, consistent with the capability of the RS-485 standard. The RS-485 standard permits the addition of any desired number of display modules 10 on any of the display boards 140 as needed, consistent with the desired flexibility of having the ability to add modules of information display quickly and economically as dictated by changes or expansion in the manufacturing processes for which the modular display board 140 will display the requisite messages.

FIG. 6 shows that, as an alternative to the series connection of FIG. 5, the display modules 10 can also be connected by a star, ring or multiple connected cable network. Accordingly, it is seen that the electrical architecture for connecting the display modules 10 to make a display board 140, and for connecting the display boards together, can be varied within the factory.

Thus, it is seen that the invention provides a modular display device that can be readily expanded and/or customized to the needs of individual manufacturing processes without requiring extensive re-engineering or manufacture of custom display devices as heretofore common in the display board industry. This allows the final assembly of the display board in either a sign shop or at the final destination where the display board will be used. In addition, the modular design makes it possible to add display modules or to rearrange the display modules, thus reconfiguring the display board in an economical and convenient manner. In addition, by maintaining a small inventory of module devices, the display boards can be readily enlarged as needed.

It will be understood that although the examples given herein relate to a display board that is used in a manufacturing facility, the attributes of the display board are also useful in the advertising industry or in sports scoreboards, or other applications. Although the example shown herein has four compartments in the housing box 30, the housing box can be made with any number of compartments, for example two or six compartments in a housing box. In addition, any color light-emitting diode can be used, and there can be one or two or more light-emitting diodes in each compartment depending upon the signaling scheme that is preferred by the users. And the light-emitting diodes can be of red, yellow, green, blue, white or any other color. While the Ethernet connection described herein is the RS-485 standard, it will be understood that the connection can also be made by the RS-232 or any other serial communication standard.

What is claimed is:

1. A modular display device comprising:
a housing module having a plurality of open face compartments, said housing module including a back wall having an access opening therein registering with each of the open face compartments,
a circuit board mounted on the back wall of the housing module and having a plurality of light-emitting diodes mounted thereon, said light-emitting diodes being energizable by the circuit board to shine through the access openings in the back wall,
and a lens attached to the housing module to close at least one of the open face compartments, and the lens having an alphanumeric or other message thereon to be backlit by the light-emitting diodes upon selective energization of the light-emitting diodes so that information is displayed.

2. The modular display device of claim 1 in which a plurality of such housings modules are mounted together side by side in order to form a display board of scalable and customizable size depending upon the number of information messages that are desired.

3. The modular display device of claim 1 further comprising the housing module having a back cover that is attached to the back wall of the housing module to cover and protect the circuit board.

4. The modular display device of claim 3 further comprising said back cover having vent openings therein to vent away heat from the circuit board.

5. The modular display device of claim 1 further comprising at least two light-emitting diodes located in each access opening and having contrasting colors so the message includes both the alphanumeric message content and also a choice of color.

6. The modular display device of claim 1 further comprising mounting brackets mounted on at least one side of each of the module boxes to enable the attachment together of a plurality of module boxes to form a large scale display device of desired size.

7. The modular display device of claim 1 further comprising each lens being a transparent or translucent plastic with an alphanumeric message thereon.

8. The modular display of claim 1 further comprising said lens being a seven segment light-emitting diode counter or alphanumeric light-emitting diode display.

9. The modular display of claim 2 in which the housing modules are connected by an Ethernet connection employing the RS-485 communication standard.

10. A modular display device comprising:
a housing module having a plurality of open face compartments, said housing module including a back wall having access openings therein registering with each of the open face compartments,
a single circuit board mounted on the back wall of the housing module and having a plurality of light-emitting diodes mounted thereon and registering with the access openings so that upon energization a light-emitting diode the resultant illumination will illuminate the open face compartment,
and a plurality of lenses bearing an alphanumeric message and being mounted on the housing module to close the open face compartment and be back lit by the illumination within the open face compartment.

11. The modular display device of claim 10 further comprising a plurality of light-emitting diodes registering with each access opening and having contrasting colors so the message includes both the alphanumeric message content and also a choice of color.

12. The modular display device of claim 10 further comprising the display device having a back cover that is attached to the back wall of the housing module to cover and protect the circuit board, said back cover having vent openings therein to vent away heat from the circuit board.

13. The modular display device of claim 10 further comprising mounting brackets mounted on at least one side of each of the housing modules to enable the attachment together of a plurality of housing modules to form a large scale display device of desired size.

14. The modular display device of claim 10 comprising a plurality of said housing modules joined together side-by-side to make a large scale display board of desired size.

15. The modular display device of claim 14 further comprising mounting brackets provided on at least one side of each of the housing modules to enable the side-by-side joining together of the housing modules.

16. The modular display device of claim 10 in which the circuit board carries at least one dip switch and at least one electrical connector, and the back cover has at least one access slot through which the dip switch and the electrical connector can be accessed by a technician.

17. The modular display device of claim 10 further comprising said module housing having four open face compartments.

18. The modular display device of claim 17 further comprising said housing module being of molded plastic construction with an interior dividing vertical wall and an interior dividing horizontal wall so that two upper open face compartment are arranged above two lower open face compartments.
